(19) United States
(12) Patent Application Publication
(10) Pub. No.: US 2025/0285844 A1
(43) Pub. Date: Sep. 11, 2025

(54) SUSCEPTOR

(71) Applicant: NGK INSULATORS, LTD., Nagoya-City (JP)

(72) Inventor: Kentaro KIMURA, Handa-Shi (JP)

(73) Assignee: NGK INSULATORS, LTD., Nagoya-City (JP)

(21) Appl. No.: 18/805,646

(22) Filed: Aug. 15, 2024

Related U.S. Application Data
(63) Continuation of application No. PCT/JP2024/008613, filed on Mar. 6, 2024.

(51) Int. Cl. H01J 37/32

(52) U.S. Cl. CPC H01J 37/32715; H01J 37/32082; H01J 2237/002

(57) ABSTRACT

There is provided a susceptor including: a ceramic plate including a first surface and a second surface; an internal electrode embedded in the ceramic plate; a metal layer provided as an RF electrode on an entirety or a part of the second surface of the ceramic plate; a cooling plate provided at a predetermined distance from the second surface; a heat transfer space present between the metal layer and the cooling plate, and configured to enable heat transfer through gas; a seal member provided along outer peripheries of the ceramic plate and the cooling plate between the ceramic plate and the cooling plate, to impart airtightness to the heat transfer space; and an RF conduction member provided at a position on an inner peripheral side of the seal member between the ceramic plate and the cooling plate to secure electric connection between the metal layer and the cooling plate.

### CROSS-REFERENCE TO RELATED APPLICATION

This application is a continuation application of PCT/JP2024/008613 filed Mar. 6, 2024, the entire contents of which are incorporated herein by reference.

### BACKGROUND OF THE INVENTION

### 1. Field of the Invention

The present disclosure relates to a susceptor.

### 2. Description of the Related Art

In a film formation apparatus and an etching apparatus for a semiconductor manufacturing process, a susceptor is used to support a wafer. As such a susceptor, a susceptor including a ceramic plate on which the wafer is to be placed, an RF electrode inducing generation of high-frequency plasma, and a cooling plate is widely used. The ceramic plate generally has a configuration in which an internal electrode such as a heater electrode, an RF electrode, an electrostatic chuck (ESC) electrode is embedded inside a ceramic substrate made of aluminum nitride (AlN) or the like excellent in heat resistance and corrosion resistance.

Patent Literature 1 (JP2023-5203A) discloses a substrate support that supports a substrate and includes a substrate attraction part including an attraction electrode for holding the substrate, and RF electrode part to which RF power is supplied, and a substrate temperature adjuster including a heater electrode for adjusting a temperature of the substrate, and discloses a stacked-layer structure in which the RF electrode part is interposed between the substrate attraction part and the substrate temperature adjuster.

Patent Literature 2 (JP6884110B) discloses an electrostatic puck assembly including an upper puck plate, a lower puck plate joined to the upper puck plate by first metal joining, a backing plate joined to a bottom surface of the lower puck plate by second metal joining, and an electrically conductive gasket. The upper puck plate contains AlN or Al₂O₃, and has a first thermal expansion coefficient. The upper puck plate further includes one or more heating elements, and one or more electrodes for electrostatically fixing the substrate. The lower puck plate contains a material having the first thermal expansion coefficient or a second thermal expansion coefficient. The backing plate is a plate having a disc shape and containing AlN or Al₂O₃, and has a first diameter less than a second diameter of the lower puck plate. The electrically conductive gasket is disposed on the bottom surface of the lower puck plate outside the first diameter of the backing plate.

### CITATION LIST

### Patent Literature

Patent Literature 1: JP2023-5203A

Patent Literature 2: JP6884110B

### SUMMARY OF THE INVENTION

As a typical example of the RF electrode in the existing susceptor, a metal mesh (for example, molybdenum mesh) embedded in the ceramic plate is known. In such an existing structure, the metal mesh tends to undulate due to flexibility thereof. Therefore, it is difficult to control uniformization of the distance between the top surface of the ceramic plate and the metal mesh in plane, important to realize a desired RF function, and incident ion concentration generated by voltage application to the RF electrode is varied due to deviation of in-plane distribution of the distance. Therefore, it is desirable to provide a configuration in which the in-plane variation of the distance between the top surface of the ceramic plate and the metal mesh can be easily suppressed.

In the semiconductor manufacturing apparatus for etching, the susceptor is desired to have high heat removal property in order to promptly dissipate heat input from the plasma from the susceptor. However, in the susceptor having high heat removal property, an expensive joining method such as metal diffusion joining (for example, TCB joining) is currently adopted for connection between the ceramic plate and the cooling plate. Therefore, it is advantageous if the ceramic plate and the cooling plate are connected by an inexpensive method.

The present inventors have found that by disposing, on a bottom surface side of the ceramic plate embedded with the internal electrode, a metal layer as an RF electrode, a heat transfer space sealed by a seal member, and a cooling plate in order and also disposing, in the heat transfer space, an RF conduction member electrically connecting the metal layer and the cooling plate, it is possible to provide a susceptor that has an inexpensive configuration suitable for suppressing in-plane variation of a distance between a top surface of the ceramic plate and the RF electrode.

An object of the present invention is to provide a susceptor having an inexpensive configuration that includes an RF function and is suitable for suppressing in-plane variation of a distance between a top surface of a ceramic plate and an RF electrode.

The present disclosure provides the following aspects.

### Aspect 1

A susceptor comprising:
a ceramic plate having a disc shape and including a first surface and a second surface;
an internal electrode embedded in the ceramic plate;
a metal layer provided as an RF electrode on an entirety or a part of the second surface of the ceramic plate;
a cooling plate having a disc shape and provided at a predetermined distance from the second surface of the ceramic plate;
a heat transfer space present between the metal layer and the cooling plate, and configured to enable heat transfer through gas;
a seal member provided along outer peripheries of the ceramic plate and the cooling plate between the ceramic plate and the cooling plate, to impart airtightness to the heat transfer space; and
an RF conduction member provided at a position on an inner peripheral side of the seal member between the ceramic plate and the cooling plate, and configured to secure electric connection between the metal layer and the cooling plate.

### Aspect 2

The susceptor according to aspect 1, wherein the metal layer has a thickness of 3 μm to 500 μm.

### Aspect 3

The susceptor according to aspect 1 or 2, wherein the metal layer is a layer formed by printing or plating, or a metal sheet.

### Aspect 4

The susceptor according to any one of aspects 1 to 3, wherein the ceramic plate contains aluminum nitride and/or aluminum oxide.

### Aspect 5

The susceptor according to any one of aspects 1 to 4, wherein the cooling plate is made of a metal or a metal matrix composite.

### Aspect 6

The susceptor according to any one of aspects 1 to 5, wherein the RF conduction member includes an elongated metal part wound in a spiral shape.

### Aspect 7

The susceptor according to any one of aspects 1 to 6, further comprising a terminal rod connected to the internal electrode, and configured to extend in a direction away from the second surface across the second surface, the metal layer, the heat transfer space, and the cooling plate.

### Aspect 8

The susceptor according to aspect 7, wherein the cooling plate includes an opening hole through which the terminal rod passes, and a surface of the opening hole is covered with an insulating member to insulate the terminal rod from the cooling plate.

### Aspect 9

The susceptor according to any one of aspects 1 to 8, wherein the cooling plate includes an internal space for a cooling medium to flow inside the cooling plate.

### Aspect 10

The susceptor according to any one of aspects 1 to 9, further comprising a fixing member provided along the outer periphery of the susceptor, the fixing member fixing the ceramic plate, the metal layer, the seal member, the RF conduction member, and the cooling plate to be brought into contact with one another.

### Aspect 11

The susceptor according to aspect 10, wherein the ceramic plate includes a small-diameter portion having a relatively small diameter and providing the first surface, and a large-diameter portion having a relatively large diameter and providing the second surface, such that the large-diameter portion and the small-diameter portion form a step portion, and wherein the fixing member is configured to be engageable with the step portion.

### BRIEF DESCRIPTION OF THE DRAWINGS

FIG. 1 is a schematic cross-sectional view illustrating an example of a susceptor according to the present disclosure.

FIG. 2 is a schematic plan view of the susceptor illustrated in FIG. 1.

FIG. 3 is a schematic perspective view illustrating an example of an RF conduction member.

### DETAILED DESCRIPTION OF THE INVENTION

A susceptor according to the present invention is a table for supporting a wafer, used for a semiconductor manufacturing apparatus, in particular, for a film formation apparatus or an etching apparatus for a semiconductor manufacturing process. The susceptor according to the present invention preferably includes a ceramic heater for a semiconductor film formation apparatus. Typical examples of the film formation apparatus include a CVD (chemical vapor deposition) apparatus (for example, thermal CVD apparatus, plasma CVD apparatus, optical CVD apparatus, and MOCVD apparatus), and a PVD (physical vapor deposition) apparatus, and the film formation apparatus is especially preferably a plasma CVD apparatus.

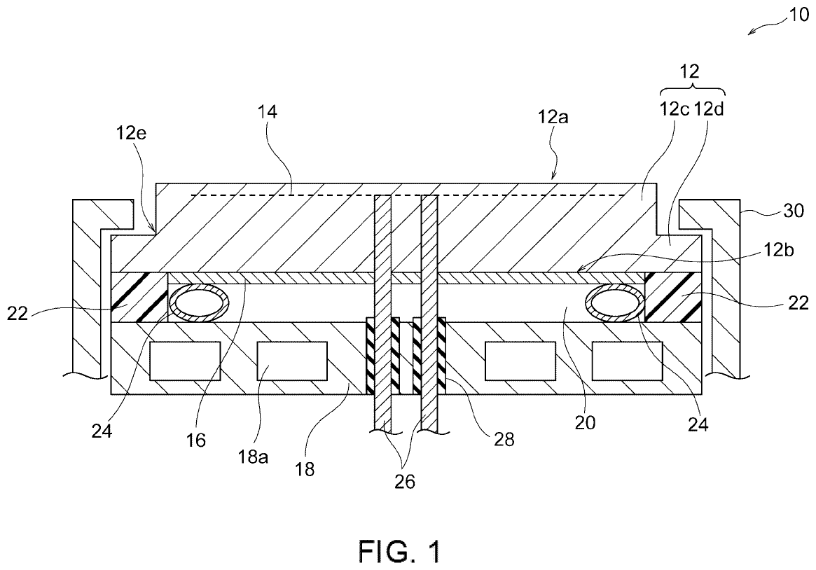

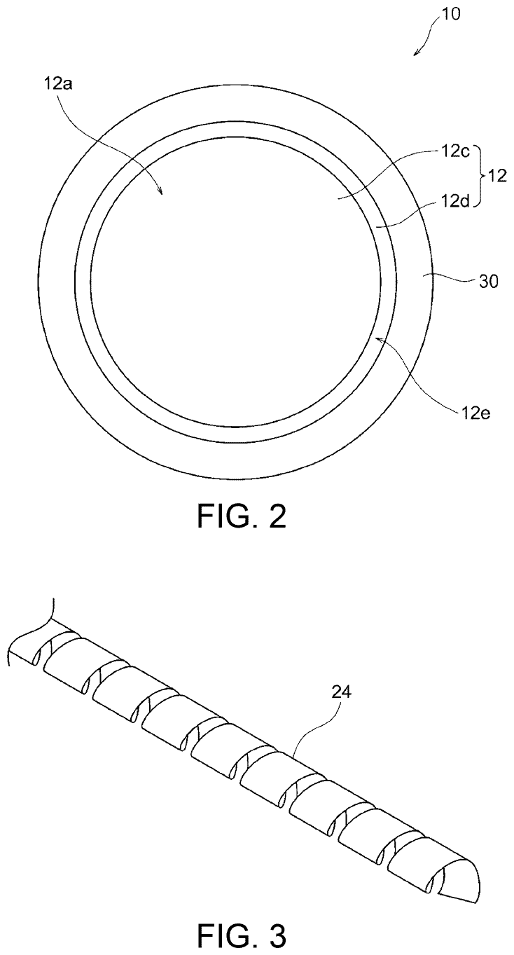

FIGS. 1 and 2 illustrate one aspect of a susceptor 10. The susceptor 10 illustrated in FIG. 1 includes a ceramic plate 12, an internal electrode 14, a metal layer 16, a cooling plate 18, a heat transfer space 20, a seal member 22, and an RF conduction member 24. The ceramic plate 12 has a disc shape and includes a first surface 12a and a second surface 12b. The internal electrode 14 is embedded in the ceramic plate 12. The metal layer 16 is provided as an RF electrode on an entirety or a part of the second surface 12b of the ceramic plate 12. The cooling plate 18 has a disc shape, and is provided at a predetermined distance from the second surface 12b of the ceramic plate 12. The heat transfer space 20 is a space enabling heat transfer through gas, and is present between the metal layer 16 and the cooling plate 18. The seal member 22 is provided along outer peripheries of the ceramic plate 12 and the cooling plate 18 between the ceramic plate 12 and the cooling plate 18, so as to impart airtightness to the heat transfer space 20. The RF conduction member 24 is a member securing electric connection between the metal layer 16 and the cooling plate 18, and is provided at a position on an inner peripheral side of the seal member 22 between the ceramic plate 12 and the cooling plate 18. In this way, by disposing, on the second surface 12b side of the ceramic plate 12 embedded with the internal electrode 14, the metal layer 16 as the RF electrode, the heat transfer space 20 sealed by the seal member 22, and the cooling plate 18 in order and also disposing, in the heat transfer space 20, the RF conduction member 24 electrically connecting the metal layer 16 and the cooling plate 18, it is possible to provide the susceptor that has an inexpensive configuration suitable for suppressing in-plane variation of a distance between the first surface 12a of the ceramic plate 12 and the metal layer 16 (RF electrode).

As described above, in the existing structure, the metal mesh tends to undulate due to flexibility thereof. Therefore, it is difficult to control uniformization of the distance between the top surface of the ceramic plate and the metal mesh in plane, important to realize a desired RF function, and incident ion concentration generated by voltage application to the RF electrode is varied due to deviation of in-plane distribution of the distance. In other words, the RF function is affected by the distance between the top surface of the ceramic plate and the RF electrode. Therefore, when the in-plane variation occurs on the above-described distance in a product, incidence on the wafer is varied, which causes characteristic variation of a wafer surface. For example, in a case where the wafer surface is etched by incidence of ions or radicals, when electron density and a temperature are varied due to the above-described in-plane variation, product performance is largely affected. Therefore, it is desirable to provide a configuration in which the in-plane variation of the distance between the top surface of the ceramic plate and the metal mesh can be easily suppressed. In this regard, according to the present invention, the RF electrode such as a metal mech is not embedded in the ceramic plate 12, but the metal layer 16 is formed on an entirety or a part of the second surface 12b of the ceramic plate 12, and the metal layer 16 is used as the RF electrode. In the configuration, after the second surface 12b of the ceramic plate 12 is processed so as to improve smoothness, the metal layer 16 can be formed by an inexpensive method such as printing, plating, and sheet bonding, and can be used as the RF electrode. For example, desired flatness and parallelism (relative to first surface 12a) are imparted to the second surface 12b of the ceramic plate 12 by a common machining process or the like, and then, the metal layer 16 is formed on the second surface 12b of the ceramic plate 12, which makes it possible to easily secure a parallelism of a top surface of the metal layer 16 relative to the first surface 12a of the ceramic plate 12. Performing formation of the ceramic plate 12 and formation of the metal layer 16 in different processes as described above makes it possible to reduce a manufacturing cost. Accordingly, it is possible to suppress the in-plane variation of the distance between the first surface 12a of the ceramic plate 12 and the metal layer 16 (RF) electrode. As a result, it is possible to inexpensively realize the desired RF function.

In the semiconductor manufacturing apparatus for etching, the susceptor is desired to have high heat removal property in order to promptly dissipate heat input from the plasma from the susceptor. However, in the susceptor having high heat removal property, an expensive joining method such as metal diffusion joining (for example, TCB joining) is currently adopted for connection between the ceramic plate and the cooling plate. Therefore, it is advantageous if the ceramic plate and the cooling plate are connected by an inexpensive method. In this regard, according to the present invention, the cooling plate is not joined to the second surface 12b of the ceramic plate 12 by the expensive joining method, but the cooling plate 18 is disposed through the heat transfer space 20 sealed by the seal member 22. The heat transfer space 20 is formed when the seal member 22 is provided along the outer peripheries of the ceramic plate 12 and the cooling plate 18 so as to impart airtightness to the heat transfer space 20, and enables heat transfer through gas. In addition, electric connection between the metal layer 16 as the RF electrode and the cooling plate 18 is secured by the RF conduction member 24 provided at the position on the inner peripheral side of the seal member 22. These configurations are inexpensively obtainable because the expensive joining method such as the metal diffusion joining (for example, TCB joining) is not required. Nevertheless, the heat generated in the ceramic plate 12 can be efficiently removed through the heat transfer space 20 and the cooling plate 18 adjacent thereto. In addition, since the heat transfer space 20 is sealed by the seal member 22, it is possible to prevent corrosive gas used for cleaning in a chamber from entering the heat transfer space 20. As a result, it is possible to avoid corrosion of the metal layer 16 by the corrosive gas.

In terms of excellent heat conductivity, high electric insulation property, thermal expansion characteristics close to silicon, and the like, a main portion (namely, ceramic substrate) of the ceramic plate 12 other than embedded members such as the internal electrode 14 preferably contains aluminum nitride and/or aluminum oxide, and more preferably contains aluminum nitride.

The ceramic plate 12 has a disc shape. However, the ceramic plate 12 formed in the disc shape is not required to have a complete circular shape in a planar view, and the ceramic plate 12 may have an incomplete circular shape partially cut away, such as an orientation flat in a planar view. A size of the ceramic plate 12 is appropriately determined based on a diameter of the wafer assumed to be used and is not particularly limited. In a case of a circular shape, a diameter of the ceramic plate 12 is typically 150 mm to 450 mm, and is typically 320 mm to 380 mm especially for a 300 mm silicon wafer. A thickness of the ceramic plate 12 is typically 10 mm to 25 mm.

The first surface 12a and the second surface 12b of the ceramic plate 12 are preferably flat and parallel to each other. As described above, the desired flatness and parallelism (relative to first surface 12a) are imparted to the second surface 12b of the ceramic plate 12 by a common machining process or the like, and then, the metal layer 16 is formed on the second surface 12b of the ceramic plate 12, which makes it possible to effectively suppress the in-plane variation of the distance between the first surface 12a of the ceramic plate 12 and the metal layer 16 (RF electrode). As a result, it is possible to inexpensively realize the desired RF function. For example, the flatness of the second surface 12b is preferably 50 μm or less, and more preferably 20 μm or less. The parallelism of the second surface 12b relative to the first surface 12a is preferably 50 μm or less, and more preferably 20 um or less. The flatness and the parallelism are terms defined in JIS B 0621-1984. More specifically, the flatness is defined as a minimum interval between two planes that are geometrically parallel to each other when a planar body (second surface 12b) is sandwiched between the two planes. The parallelism of the planar body (second surface 12b) to a datum plane (corresponding to first surface 12a) is defined as an interval between two planes that are geometrically parallel to each other and are parallel to the datum plane (corresponding to first surface 12a) when the planar body (second surface 12b) is sandwiched between the two planes.

Preferably, the ceramic plate 12 includes a small-diameter portion 12c having a relatively small diameter and providing the first surface 12a, and a large-diameter portion 12d having a relatively large diameter and providing the second surface 12b, and the large-diameter portion 12d and the small-diameter portion 12c form a step portion 12e. The ceramic plate 12 having the shape is advantageous in terms of attachment easiness of a fixing member 30 described below.

The internal electrode 14 is an electrode embedded in the ceramic plate 12, and includes a heater electrode or an ESC electrode or both. Although not particularly limited, for example, the heater electrode may be a conductive coil laid in a one-stroke manner over an entire surface of the ceramic plate 12. Terminal rods 26 for power supply are connected to respective ends of the heater electrode, and the heater electrode is connected to a heater power supply (not illustrated) through the terminal rods 26. The terminal rods 26 connected to the internal electrode 14 preferably extend in a direction away from the second surface 12b across the second surface 12b, the metal layer 16, the heat transfer space 20, and the cooling plate 18. When power is supplied from the heater power supply, the heater electrode generates heat to heat the wafer placed on the top surface of the ceramic plate 12. The heater electrode is not limited to the coil, and may be, for example, a ribbon (long thin plate), a mesh, or a print. The ESC electrode is an abbreviation for an electrostatic chuck (ESC) electrode, and is also referred to as an electrostatic electrode. The ESC electrode is preferably a circular thin layer electrode having a diameter slightly smaller than the diameter of the ceramic plate 12, and may be, for example, a mesh-shaped electrode obtained by knitting thin metal wires to a mesh sheet. The terminal rods 26 for power supply are connected to the ESC electrode, and the terminal rods may be connected to an external power supply (not illustrated). Even in this case, the terminal rods 26 connected to the internal electrode 14 as the ESC electrode preferably extend in the direction away from the second surface 12b across the second surface 12b, the metal layer 16, the heat transfer space 20, and the cooling plate 18. When a voltage is applied from the external power supply, the ESC electrode chucks the wafer placed on the top surface of the ceramic plate 12 with Johnson Rahbeck force. The internal electrode 14 may include both the heater electrode and the ESC electrode. In this case, the heater electrode and the ESC electrode may be embedded as separate internal electrodes 14 at different depth positions in the ceramic plate 12. Alternatively, only one of the heater electrode or the ESC electrode may be embedded as the internal electrode 14 in the ceramic plate 12.

The metal layer 16 is provided as the RF electrode on an entirety or a part of the second surface 12b of the ceramic plate 12. A thickness of the metal layer 16 is preferably 3 μm to 500 μm, more preferably 20 μm to 300 μm, and further preferably 50 μm to 200 μm. Such a thin metal layer 16 is easily fitted to a surface shape of the second surface 12b of the ceramic plate 12, and accordingly, deformation such as undulation is less likely to occur. Therefore, it is possible to more effectively suppress the in-plane variation of the distance between the first surface 12a of the ceramic plate 12 and the metal layer 16 (RF electrode). In that sense, the metal layer 16 is preferably a layer formed by printing or plating. Further, the metal layer 16 may be a metal sheet, and in this case, the metal sheet may be bonded to the second surface 12b by an inexpensive method such as an adhesive.

A material of the metal layer 16 is not particularly limited as long as the metal layer 16 functions as the RF electrode, but the metal layer 16 is preferably made of a metal having a thermal expansion coefficient close to a thermal expansion coefficient of aluminum nitride or aluminum oxide, such as molybdenum, tungsten, and zirconium, or an alloy thereof.

The cooling plate 18 is a disc-shaped plate provided at a predetermined distance from the second surface 12b of the ceramic plate 12. The cooling plate 18 can have a configuration of a cooling plate generally used for a ceramic heater and electrostatic chuck. The cooling plate 18 is preferably made of a metal such as aluminum and an aluminum alloy in terms of RF supply, heat removal property, and a cost, but may be made of a metal matrix composite (MMC) such as SiSiCTi (composite material containing Si, SiC, and Ti). The typical cooling plate 18 includes an internal space providing a flow path 18a for a cooling medium to flow inside the cooling plate 18. For example, the flow path 18a is connected to a refrigerant supply path and a refrigerant discharge path (not illustrated). The refrigerant discharged from the refrigerant discharge path is adjusted in temperature, and is then returned to the refrigerant supply path.

Preferably, the cooling plate 18 includes an opening hole through which the terminal rods 26 pass, and a surface of the opening hole is covered with an insulating member 28 to insulate the terminal rods 26 from the cooling plate 18 (made of, for example, metal).

The heat transfer space 20 is a space that is present between the metal layer 16 and the cooling plate 18 and enables heat transfer through gas. The typical heat transfer space 20 is a sealed space surrounded by the ceramic plate 12 including the metal layer 16 on the second surface 12b, the cooling plate 18, and the seal member 22. In use, the heat transfer space 20 is filled with gas for heat transfer. Preferable examples of the gas filled in the heat transfer space 20 include helium (He).

The seal member 22 is provided along the outer peripheries of the ceramic plate 12 and the cooling plate 18 between the ceramic plate 12 and the cooling plate 18, so as to impart airtightness to the heat transfer space 20. Imparting airtightness to the heat transfer space 20 in such a manner makes it possible to prevent corrosive gas used for cleaning in the chamber from entering the heat transfer space 20. As a result, it is possible to avoid corrosion of the metal layer 16 by the corrosive gas. The seal member 22 is not particularly limited as long as the seal member 22 has heat resistance necessary for the susceptor 10, and a common inexpensive seal member such as an O-ring and a metal seal can be used as the seal member 22. Therefore, in the present invention, an expensive seal member having a special shape and/or made of a special material is not used as the seal member 22, which is advantageous in terms of a cost.

The RF conduction member 24 is a member for securing electric connection between the metal layer 16 and the cooling plate 18, and is provided at the position on the inner peripheral side of the seal member 22 between the ceramic plate 12 and the cooling plate 18. To cause the metal layer 16 to function as the RF electrode, it is necessary to connect the metal layer 16 to an RF power supply (not illustrated) or to ground the metal layer 16. However, since the heat transfer space 20 is present just below the metal layer 16 in the susceptor 10, means for supplying RF to the metal layer 16 is necessary on the cooling plate 18 side. In this regard, since the RF conduction member 24 is interposed between the metal layer 16 and the cooling plate 18, electric connection between the metal layer 16 and the cooling plate 18 is secured. Therefore, by connecting the cooling plate 18 to the RF power supply (not illustrated) or by grounding the cooling plate 18, it is possible to cause the metal layer 16 to function as the RF electrode.

The RF conduction member 24 is not particularly limited as long as a member can secure electric connection between the metal layer 16 and the cooling plate 18, but the RF conduction member 24 preferably includes an elongated metal part wound in a spiral shape as illustrated in FIG. 3. The elongated metal part may have a plate shape, a rod shape, or other optional shape. As the elongated metal part wound in the spiral shape, a commercially-available spiral spring gasket is preferably used because of being inexpensively obtainable.

The susceptor 10 preferably further includes the fixing member 30 provided along the outer periphery of the susceptor 10, and the fixing member 30 is preferably configured to fix the ceramic plate 12, the metal layer 16, the seal member 22, the RF conduction member 24, and the cooling plate 18 to be brought into contact with one another. For example, in a case where the ceramic plate 12 includes the small-diameter portion 12c and the large-diameter portion 12d to form the step portion 12e as described above, the fixing member 30 is preferably configured to be engageable with the step portion 12e. The fixing member 30 is not particularly limited as long as the fixing member 30 can fix the ceramic plate 12, the metal layer 16, the seal member 22, the RF conduction member 24, and the cooling plate 18 to be brought into contact with one another, and a well-known fixing member such as a clamp and a ring-shaped member (provided along outer periphery of ceramic plate 12) may be used. In a case of the clamp, the ceramic plate 12 (for example, portion of large-diameter portion 12d extending as step portion 12e), the seal member 22, the cooling plate 18, and the like are sandwiched and fixed by a fixing mechanism of the clamp. In a case of the ring-shaped member, the ring-shaped member is placed on the ceramic plate 12 (for example, portion of large-diameter portion 12d extending as step portion 12e), and the ring-shaped member is fixed to the cooling plate 18 or the other apparatus member so as to be pressed against the cooling plate 18 by fixing means such as a screw.

What is claimed is:

1. A susceptor comprising:
a ceramic plate having a disc shape and including a first surface and a second surface;
an internal electrode embedded in the ceramic plate;
a metal layer provided as an RF electrode on an entirety or a part of the second surface of the ceramic plate;
a cooling plate having a disc shape and provided at a predetermined distance from the second surface of the ceramic plate;
a heat transfer space present between the metal layer and the cooling plate, and configured to enable heat transfer through gas;
a seal member provided along outer peripheries of the ceramic plate and the cooling plate between the ceramic plate and the cooling plate, to impart airtightness to the heat transfer space; and
an RF conduction member provided at a position on an inner peripheral side of the seal member between the ceramic plate and the cooling plate, and configured to secure electric connection between the metal layer and the cooling plate.

2. The susceptor according to claim 1, wherein the metal layer has a thickness of 3 μm to 500 μm.

3. The susceptor according to claim 1, wherein the metal layer is a layer formed by printing or plating, or a metal sheet.

4. The susceptor according to claim 1, wherein the ceramic plate contains aluminum nitride and/or aluminum oxide.

5. The susceptor according to claim 1, wherein the cooling plate is made of a metal or a metal matrix composite.

6. The susceptor according to claim 1, wherein the RF conduction member includes an elongated metal part wound in a spiral shape.

7. The susceptor according to claim 1, further comprising a terminal rod connected to the internal electrode, and configured to extend in a direction away from the second surface across the second surface, the metal layer, the heat transfer space, and the cooling plate.

8. The susceptor according to claim 7, wherein the cooling plate includes an opening hole through which the terminal rod passes, and a surface of the opening hole is covered with an insulating member to insulate the terminal rod from the cooling plate.

9. The susceptor according to claim 1, wherein the cooling plate includes an internal space for a cooling medium to flow inside the cooling plate.

10. The susceptor according to claim 1, further comprising a fixing member provided along the outer periphery of the susceptor, the fixing member fixing the ceramic plate, the metal layer, the seal member, the RF conduction member, and the cooling plate to be brought into contact with one another.

11. The susceptor according to claim 10, wherein the ceramic plate includes a small-diameter portion having a relatively small diameter and providing the first surface, and a large-diameter portion having a relatively large diameter and providing the second surface, such that the large-diameter portion and the small-diameter portion form a step portion, and wherein the fixing member is configured to be engageable with the step portion.
